(19) United States
(12) Patent Application Publication
(10) Pub. No.: US 2009/0108741 A1
(43) Pub. Date: Apr. 30, 2009

(54) ORGANIC EL DISPLAY DEVICE AND METHOD OF MANUFACTURING THE SAME

(76) Inventors: Shuhei YOKOYAMA, Ishikawa-gun (JP); Masuyuki Oota, Hakusan-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/250,134

(22) Filed: Oct. 13, 2008

(30) Foreign Application Priority Data
Oct. 26, 2007 (JP) 2007-279247

(51) Int. Cl. H01J 1/62; H01J 9/00

(52) U.S. Cl. 313/504; 445/24

(57) ABSTRACT

An organic EL display device includes a first organic EL element which emits light of a first color and a second organic EL element which emits light of a second color that differs from the first color, the first organic EL element and the second organic EL element being arranged on a substrate, wherein each of the first organic EL element and the second organic EL element includes a first electrode, a second electrode which is opposed to the first electrode, and an organic layer which is interposed between the first electrode and the second electrode, the organic layer of the first organic EL element and the organic layer of the second organic EL element are formed of an identical material, and a light emission function of the first color is substantially lost in the organic layer of the second organic EL element.

### CROSS-REFERENCE TO RELATED APPLICATIONS

This application is based upon and claims the benefit of priority from prior Japanese Patent Application No. 2007-279247, filed Oct. 26, 2007, the entire contents of which are incorporated herein by reference.

### BACKGROUND OF THE INVENTION

1. Field of the Invention

The present invention relates to an organic electroluminescence (EL) display technology.

2. Description of the Related Art

There has been a rapidly increasing demand for flat-panel display devices, which are represented by liquid crystal display devices, by virtue of their features of smaller thickness, lighter weight and lower power consumption, compared to CRT displays. The flat-panel display devices have been applied to various displays of portable information terminal devices, large-size televisions, etc. In recent years, display devices using organic electroluminescence (EL) elements have vigorously been developed, by virtue of their features of self-emission, a higher response speed, a wider viewing angle, a higher contrast, still smaller thickness and lighter weight, compared to the liquid crystal display devices.

In the organic EL element, holes are injected from a hole injection electrode (anode), electrons are injected from an electron injection electrode (cathode), and the holes and electrons are recombined in a light emitting layer, thereby producing light. In order to obtain full-color display, it is necessary to form pixels which emit red (R) light, green (G) light and blue (B) light, respectively. It is necessary to selectively apply light-emitting materials, which emit lights with different light emission spectra, such as red, green and blue, to light-emitting layers of organic EL elements which constitute the red, green and blue pixels.

As a method for selectively applying such light-emitting materials, there is known a method, as disclosed in Jpn. Pat. Appln. KOKAI Publication No. 2003-157973, wherein in the case of using low-molecular-weight organic EL materials of which films are formed by a vacuum evaporation method, mask evaporation is performed independently for respective color pixels by using a metallic fine mask having openings in association with the respective color pixels.

In the mask evaporation method using the metallic fine mask, however, a sufficient precision cannot be obtained when a high fineness (resolution) is required for the display device and pixels become finer. As a result, a so-called color mixture defect, by which light-emitting materials of respective colors are mixed, occurs frequently, and normal display cannot be obtained. The reason is, in part, that in the case of the metallic mask, unlike a photomask which is used in so-called photolithography, the size and position of an opening are greatly varied due to low initial processing precision as well as thermal expansion or strain by radiation heat of an evaporation source.

In addition, the precision of the mask evaporation using the metallic mask becomes lower as the size of the mask increases, and an increase in size of the display device is limited.

### BRIEF SUMMARY OF THE INVENTION

The object of the present invention is to provide an organic EL display device which can display a multi-color image with high fineness, and a method of manufacturing the organic EL display device.

According to a first aspect of the present invention, there is provided an organic EL display device comprising: a first organic EL element which emits light of a first color and a second organic EL element which emits light of a second color that differs from the first color, the first organic EL element and the second organic EL element being arranged on a substrate, wherein each of the first organic EL element and the second organic EL element includes a first electrode, a second electrode which is opposed to the first electrode, and an organic layer which is interposed between the first electrode and the second electrode, the organic layer of the first organic EL element and the organic layer of the second organic EL element are formed of an identical material, and a light emission function of the first color is substantially lost in the organic layer of the second organic EL element.

According to a second aspect of the present invention, there is provided a method of manufacturing an organic EL display device including a first organic EL element which emits light of a first color and a second organic EL element which emits light of a second color that differs from the first color, the first organic EL element and the second organic EL element being arranged on a substrate, wherein each of the first organic EL element and the second organic EL element includes a first electrode, a second electrode which is opposed to the first electrode, and an organic layer which is interposed between the first electrode and the second electrode, a step of forming the organic layer comprising: a step of forming a mixture layer, in which a host material, a first light-emitting material with a light emission function of the first color and a second light-emitting material with a light emission function of the second color are mixed, in a region where the first organic EL element and the second organic EL element are formed; and a step of covering a region, where the first organic EL element is formed, with a mask, and irradiating a region, where the second organic EL element is formed, with electromagnetic waves which are capable of losing the light emission function of the first light-emitting material.

The present invention can provide an organic EL display device which can display a multi-color image with high fineness, without using a metallic fine mask for patterning and forming an organic layer in a manufacturing process of the organic EL display device, and a method of manufacturing the organic EL display device.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a plan view which schematically shows an organic EL display device according to an embodiment of the present invention;

FIG. 2 is a cross-sectional view which schematically shows an example of the structure that is adoptable in the display device shown in FIG. 1;

FIG. 3 is a cross-sectional view which schematically shows an example of the structure that is adoptable in an organic EL element included in the display device shown in FIG. 2;

FIG. 4 is a plan view schematically showing an example of arrangement of pixels, which is adoptable in the display device shown in FIG. 2;

FIG. 5 is a graph showing a light absorption spectrum of a light-emitting material which is adopted in the display device shown in FIG. 2;

FIG. 6 schematically shows an example of a process flow of the organic EL element shown in FIG. 3;

FIG. 7A illustrates the outline of a co-evaporation step using point-source-type evaporation sources;

FIG. 7B illustrates the outline of a co-evaporation step using a line-source-type evaporation source;

FIG. 7C is a view for explaining a density distribution of each light-emitting material in an organic layer in the case of using the line-source-type evaporation source;

FIG. 8 schematically illustrates an electromagnetic wave radiation step;

FIG. 9 schematically illustrates another electromagnetic wave radiation step;

FIG. 10 shows one principle for controlling the emission light colors of pixels in the present invention;

FIG. 11 is a cross-sectional view which schematically shows another example of the structure that is adoptable in the organic EL element included in the display device shown in FIG. 2;

FIG. 12 is a cross-sectional view which schematically shows still another example of the structure that is adoptable in the organic EL element included in the display device shown in FIG. 2;

FIG. 13 is a cross-sectional view which schematically shows still another example of the structure that is adoptable in the organic EL element included in the display device shown in FIG. 2;

FIG. 14 is a cross-sectional view which schematically shows still another example of the structure that is adoptable in the organic EL element included in the display device shown in FIG. 2;

FIG. 15 is a cross-sectional view which schematically shows still another example of the structure that is adoptable in the organic EL element included in the display device shown in FIG. 2;

FIG. 16 is a cross-sectional view which schematically shows still another example of the structure that is adoptable in the organic EL element included in the display device shown in FIG. 2; and

FIG. 17 is a cross-sectional view which schematically shows still another example of the structure that is adoptable in the organic EL element included in the display device shown in FIG. 2.

### DETAILED DESCRIPTION OF THE INVENTION

Embodiments of the present invention will now be described in detail with reference to the accompanying drawings. In the drawings, structural elements having the same or similar functions are denoted by like reference numerals, and an overlapping description is omitted.

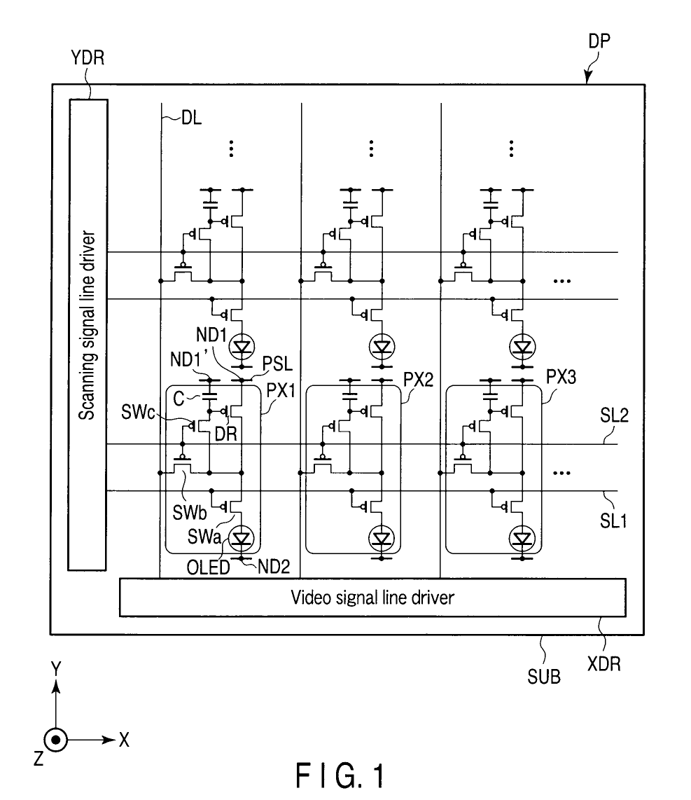

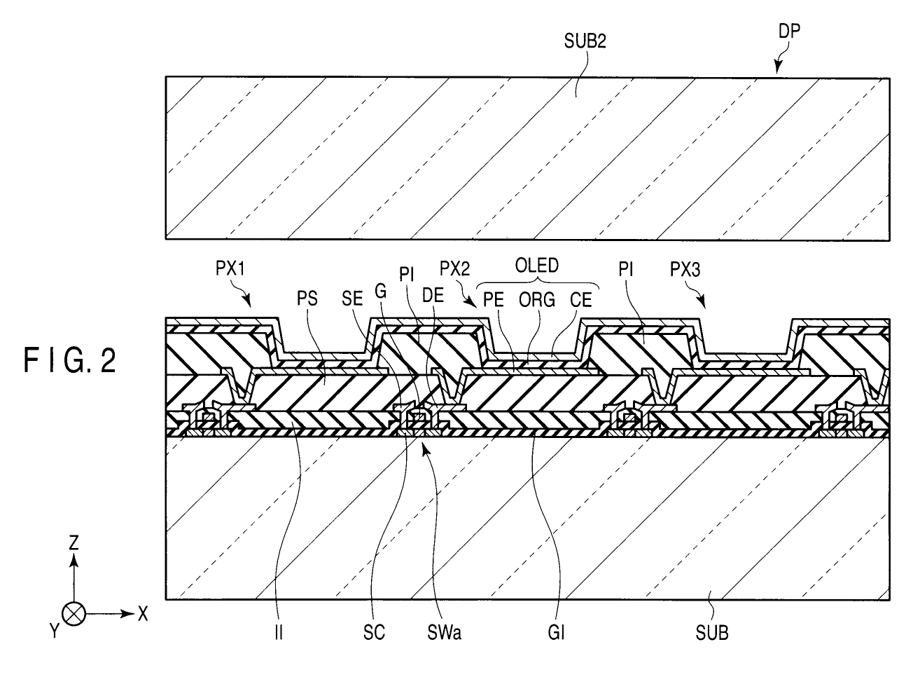

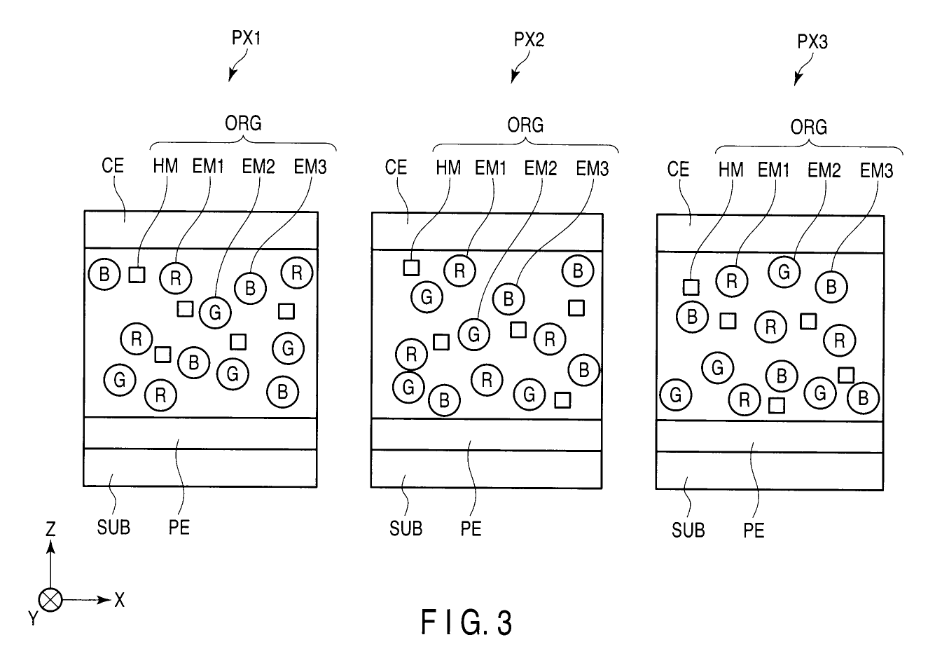

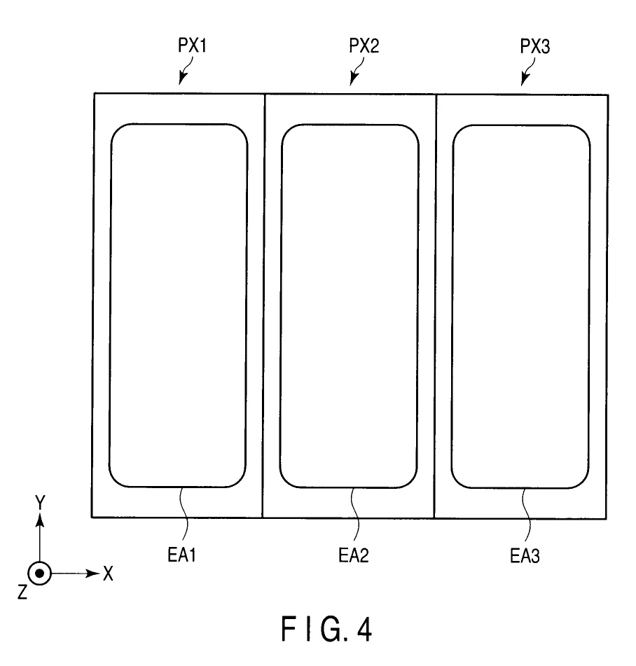

FIG. 1 is a plan view which schematically shows an organic EL display device according to an embodiment of the present invention. FIG. 2 is a cross-sectional view which schematically shows an example of the structure that is adoptable in the display device shown in FIG. 1. FIG. 3 is a cross-sectional view which schematically shows an example of the structure that is adoptable in an organic EL element included in the display device shown in FIG. 2. FIG. 4 is a plan view schematically showing an example of arrangement of pixels, which is adoptable in the display device shown in FIG. 2.

The display device shown in FIG. 1 and FIG. 2 is an organic EL display device of a top emission type, which adopts an active matrix driving method. This display device includes a display panel DP, a video signal line driver XDR and a scanning signal line driver YDR.

The display panel DP includes an insulative substrate SUB such as a glass substrate. An undercoat layer (not shown) is formed on the substrate SUB. The undercoat layer is formed by stacking an SiNₓ layer and an SiOₓ layer, in the named order, on the substrate SUB. A semiconductor pattern, which is formed of, e.g. polysilicon containing impurities, is formed on the undercoat layer.

A part of the semiconductor pattern is used as a semiconductor layer SC. Impurity diffusion regions, which are used as a source and a drain, are formed in the semiconductor layer SC. Another part of the semiconductor pattern is used as a lower electrode of a capacitor C (to be described later). The lower electrode is disposed in association with each of pixels PX1 to PX3 (to be described later).

The pixels PX1 to PX3 are arranged in an X direction in the named order, and constitute a triplet. In a display region, such triplets are arranged in the X direction and Y direction. Specifically, in the display region, a pixel string in which pixels PX1 are arranged in the Y direction, a pixel string in which pixels PX2 are arranged in the Y direction and a pixel string in which pixels PX3 are arranged in the Y direction are arranged in the X direction in the named order, and these three pixel strings are repeatedly arranged in the X direction.

The semiconductor pattern is coated with a gate insulation film G1. The gate insulation film G1 can be formed by using, e.g. TEOS (tetraethyl orthosilicate). Scanning signal lines SL1 and SL2 are formed on the gate insulation film G1. The scanning signal lines SL1 and SL2 extend in the X direction and are alternately disposed in the Y direction. The scanning signal lines SL1 and SL2 are formed of, e.g. MoW.

An upper electrode of the capacitor C is further disposed on the gate insulation film G1. The upper electrode is disposed in association with each of the pixels PX1 to PX3, and is opposed to the lower electrode. The upper electrode is formed of, e.g. MoW, and can be formed in the same fabrication step as the scanning signal lines SL1 and SL2.

The scanning signal lines SL1 and SL2 cross the semiconductor layer SC. An intersection part between the scanning signal line SL1 and the semiconductor layer SC constitutes a switching transistor SWa. An intersection part between the scanning signal line SL2 and the semiconductor layer SC constitutes switching transistors SWa and SWc. In addition, the lower electrode, the upper electrode and the gate insulation film G1, which is interposed therebetween, constitute the capacitor C. The upper electrode includes an extension part which crosses the semiconductor layer SC, and an intersection part between the extension part and the semiconductor layer SC constitutes a driving transistor DR.

In this example, the driving transistor DR and switching transistors SWa to SWc are top-gate-type p-channel thin-film transistors. In addition, a part, which is designated by a reference character G in FIG. 2, is a gate of the switching transistor SWa.

The gate insulation film G1, scanning signal lines SL1 and SL2 and the upper electrode are coated with an interlayer insulation film II. The interlayer insulation film II is formed by using SiOₓ which is deposited by, e.g. plasma CVD (chemical vapor deposition).

Video signal lines DL and power supply lines PSL are formed on the interlayer insulation film II. The video signal lines DL extend in the Y direction and are arranged in the X direction. The power supply lines PSL extend, for example, in the Y direction, and are arranged in the X direction. Source electrodes SE and drain electrodes DE are formed on the interlayer insulation film II. The source electrodes SE and drain electrodes DE connect elements in the pixels PX1 to PX3. In addition, the source electrode SE and drain electrode DE are connected to impurity diffusion regions, which are provided in the semiconductor layer SC, via contact holes which are made in the interlayer insulation film II.

The video signal line DL, power supply line PSL, source electrode SE and drain electrode DE have, for example, a three-layer structure of Mo/Al/Mo. These elements can be formed by the same process. The video signal line DL, power supply line PSL, source electrode SE and drain electrode DE are coated with a passivation film PS. The passivation film PS is formed by using, e.g. SiNₓ.

Pixel electrodes (corresponding to, for example, first electrodes) PE are disposed on the passivation film PS in association with the pixels PX1 to PX3. Each pixel electrode PE is connected to the drain electrode DE via a contact hole which is provided in the passivation film PS. The drain electrode DE is connected to the drain of the switching transistor SWa. In this example, the pixel electrode PE is an anode. As a material of the pixel electrode PE, use can be made of a light-transmissive electrically conductive material such as ITO (indium tin oxide).

A partition insulation layers PI is also formed on the passivation film PS. Through-holes are provided at those positions in the partition insulation layer PI, which correspond to the pixel electrodes PE, or slits are provided at those positions in the partition insulation layer PI, which correspond to the pixel electrodes PE. It is assumed, for example, that through-holes are provided at those positions in the partition insulation layer PI, which correspond to the pixel electrodes PE. The partition insulation layer PI is, for instance, an organic insulation layer. The partition insulation layer PI can be formed by using, for example, a photolithography technique.

An organic layer ORG is formed on each pixel electrode PE. As shown in FIG. 2, the organic layer ORG is typically a continuous film spreading over the display region including all pixels PX1 to PX3. In short, the organic layer ORG covers the pixel electrodes PE and partition insulation layer PI.

The partition insulation layer PI and organic layer ORG are coated with a counter-electrode (corresponding to, for example, a second electrode) CE. In this example, the counter-electrode CE is a cathode and is a common electrode which is shared by the pixels PX1 to PX3. The counter-electrode CE is electrically connected to an electrode wiring (not shown) which is formed in the same layer as the video signal line DL, for example, via a contact hole which is made in the passivation film PS and partition insulation layer PI.

The pixel electrode PE, organic layer ORG and counter-electrode CE constitute an organic EL element OLED which is disposed in association with the pixel electrode PE. In FIG. 4, reference numerals EA1 to EA3 denote light-emission parts of the organic EL elements OLED which are included in the pixels PX1 to PX3. Each of the light-emission parts EA1 to EA3 is a right-angled tetragonal shape which is elongated in the Y direction. In the structure shown in FIG. 4, the areas of the light-emission parts EA1 to EA3 are substantially equal.

Each of the pixels PX1 to PX3, as shown in FIG. 1, includes the driving transistor DR, switching transistors SWa to SWc, organic EL element OLED and capacitor C. As has been described above, in this example, the driving transistor DR and switching transistors SWa to SWc are p-channel thin-film transistors.

The driving transistor DR, switching transistor SWa and organic EL element OLED are connected in series in the named order between a first power supply terminal ND1 and a second power supply terminal ND2. In this example, the power supply terminal ND1 is a high-potential power supply terminal, and the power supply terminal ND2 is a low-potential power supply terminal.

The gate of the switching transistor SWa is connected to the scanning signal line SL1. The switching transistor SWb is connected between the video signal line DL and the drain of the driving transistor DR, and the gate of the switching transistor SWb is connected to the scanning signal line SL2. The switching transistor SWc is connected between the drain and gate of the driving transistor DR, and the gate of the switching transistor SWc is connected to the scanning signal line SL2. The capacitor C is connected between the gate of the driving transistor DR and a constant potential terminal ND1′. In this example, the constant potential terminal ND1′ is connected to the power supply terminal ND1.

The video signal line driver XDR and scanning signal line driver YDR are disposed on the substrate SUB. Specifically, the video signal line driver XDR and scanning signal line driver YDR are implemented by COG (chip on glass). The video signal line driver XDR and scanning signal line driver YDR may be implemented by TCP (tape carrier package), instead of COG. Alternatively, the video signal line driver XDR and scanning signal line driver YDR may be directly formed on the substrate SUB.

The video signal lines DL are connected to the video signal line driver XDR. In this example, the power supply line PSL is further connected to the video signal line driver XDR. The video signal line driver XDR outputs current signals as video signals to the video signal lines DL, and supplies a power supply voltage to the power supply line PSL.

The scanning signal lines SL1 and SL2 are connected to the scanning signal line driver YDR. The scanning signal line driver YDR outputs voltage signals as first and second scanning signals to the scanning signal lines SL1 and SL2.

When an image is to be displayed on this organic EL display device, for example, the scanning signal lines SL2 are successively scanned. Specifically, the pixels PX1 to PX3 are selected on a row-by-row basis. In a selection period in which a certain row is selected, a write operation is executed in the pixels PX1 to PX3 included in this row. In a non-selection period in which this row is not selected, a display operation is executed in the pixels PX1 to PX3 included in this row.

In the selection period in which the pixels of PX1 to PX3 of a certain row are selected, the scanning signal line driver YDR outputs, as voltage signals, scanning signals for opening (rendering non-conductive) the switching transistors SWa to the scanning signal line SL1 to which the pixels PX1 to PX3 are connected. Then, the scanning signal line driver YDR outputs, as voltage signals, scanning signals for closing (rendering conductive) the switching transistors SWb and SWc to the scanning signal line SL2 to which the pixels PX1 to PX3 are connected. In this state, the video signal line driver XDR outputs, as current signals (write current) I_{sig}, video signals to the video signal lines DL, and sets a gate-source voltage V_{gs} of the driving transistor DR at a magnitude corresponding to the video signal I_{sig}. Subsequently, the scanning signal line driver YDR outputs, as voltage signals, scanning signals for opening the switching transistors SWb and SWc to the scanning signal line SL2 to which the pixels PX1 to PX3 are connected, and then outputs, as voltage signals, scanning signals for closing the switching transistors SWa to the scanning signal line SL1 to which the pixels PX1 to PX3 are connected. Thus, the selection period ends.

In the non-selection period following the selection period, the switching transistors SWa are kept closed, and the switching transistors SWb and SWc are kept opened. In the non-selection period, a driving current I_{drv}, which corresponds in magnitude to the gate-source voltage V_{gs} of the driving transistor DR, flows in the organic EL element OLED. The organic EL element OLED emits light with a luminance corresponding to the magnitude of the driving current I_{drv}. In this case, I_{drv}≈I_{sig}, and emission light corresponding to the current signal (write current) I_{sig} can be obtained in each pixel.

The above-described example adopts the structure in which the current signal is written as the video signal in the pixel circuit. Alternatively, a structure in which a voltage signal is written as the video signal in the pixel circuit may be adopted. The invention is not particularly restricted to the above-described example. In the present embodiment, use is made of p-channel thin-film transistors.

Alternatively, n-channel thin-film transistors may be used, with the spirit of the invention being unchanged.

The sealing of the organic EL element OLED is effected by boding a sealing glass substrate SUB2, to which a desiccant is attached, by means of a sealant which is applied to the periphery of the display region.

Some examples of the present invention will now be described below.

### EXAMPLE 1

In Example 1, a 3.0-type WVGA organic EL display was fabricated. The pixel size is 82.5 μm×27.5 μm, and the number of pixels is 80033 3×480. This pixel size is the pixel size of each of the pixel PX1, pixel PX2 and pixel PX3, and in this example all the pixels have the same size. In addition, in this example, the thickness of ITO of the pixel electrode PE is 50 nm.

In Example 1, as shown in FIG. 3, the organic layer ORG was formed as a single mixture layer including at least three kinds of light-emitting materials with different emission light colors. Specifically, in the example shown in FIG. 3, the organic layer ORG includes a host material HM, a first light-emitting material EM1, a second light-emitting material EM2 and a third light-emitting material EM3. The organic layer ORG with this structure was formed as a continuous film spreading over the display region including all pixels PX1 to PX3.

As the host material HM, use was made of, for instance, 4,4′-bis(2,2′-diphenyl-ethen-1-yl)-diphenyl (BPVBI).

The first light-emitting material EM1 is formed of a luminescent organic compound or composition having a central light emission wavelength in red wavelengths. As the first light-emitting material (dopant material) EM1, use was made of, for instance, 4-(Dicyanomethylene)-2-methyl-6-(julolidin-4-yl-vinyl)-4H-pyran (DCM2).

The second light-emitting material EM2 is formed of a luminescent organic compound or composition having a central light emission wavelength in green wavelengths. As the second light-emitting material (dopant material) EM2, use was made of, for instance, tris(8-hydroxyquinolato)aluminum (Alq₃).

The third light-emitting material EM3 is formed of a luminescent organic compound or composition having a central light emission wavelength in blue wavelengths. As the third light-emitting material (dopant material) EM3, use was made of, for instance, bis[(4,6-difluorophenyl)-pyridinato-N,C2′](picorinate)iridium(III) (FIrpic).

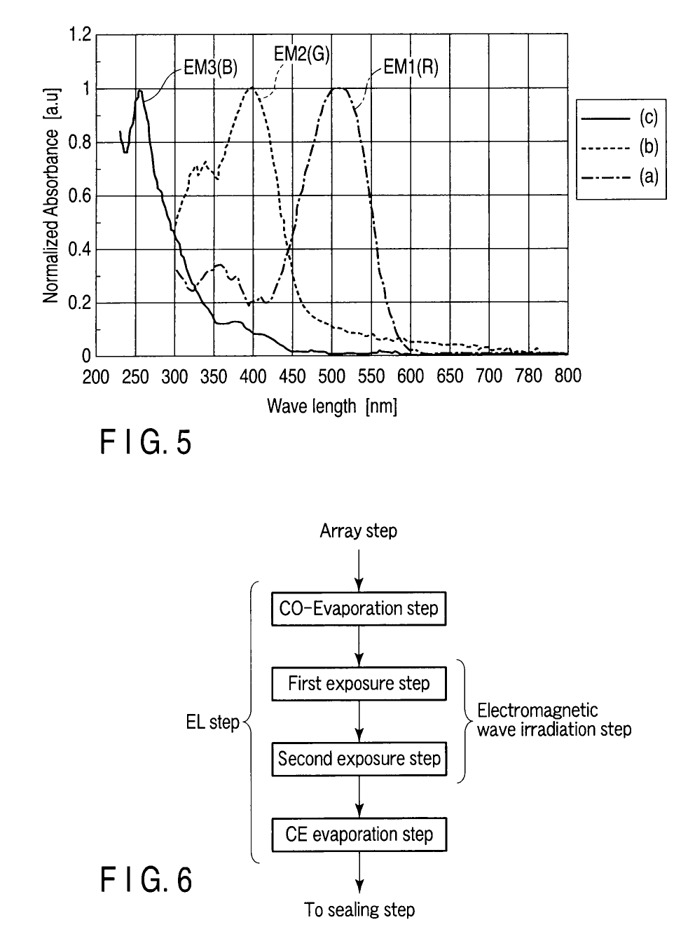

FIG. 5 shows the light absorption spectra of the first light-emitting material EM1, the second light-emitting material EM2 and the third light-emitting material EM3, which were used in this example. Specifically, the first light-emitting material EM1 has a light absorption spectrum which is indicated by (a) in FIG. 5, and has a peak of normalized absorbance in the vicinity of the wavelength of 500 nm. The second light-emitting material EM2 has a light absorption spectrum which is indicated by (b) in FIG. 5, and has a peak of normalized absorbance in the vicinity of the wavelength of 400 nm. The third light-emitting material EM3 has a light absorption spectrum which is indicated by (c) in FIG. 5, and has a peak of normalized absorbance in the vicinity of the wavelength of 250 nm.

In the wavelengths above 500 nm, the normalized absorbance of each of the second light-emitting material EM2 and third light-emitting material EM3 is less than 10%. In the wavelengths above 400 nm, the normalized absorbance of the third light-emitting material EM3 is less than 10%.

In Example 1, as described above, the pixel PX1, pixel PX2 and pixel PX3 have the organic layer ORG of the same structure, but the pixel PX1, pixel PX2 and pixel PX3 are configured to have different emission light colors. In this example, the organic EL element OLED included in the pixel PX1 emits red light, the organic EL element OLED included in the pixel PX2 emits green light, and the organic EL element OLED included in the pixel PX3 emits blue light.

In general, the color of light in the range of wavelengths of 400 nm to 435 nm is defined as purple; the color of light in the range of wavelengths of 435 nm to 480 nm is defined as blue; the color of light in the range of wavelengths of 480 nm to 490 nm is defined as greenish blue; the color of light in the range of wavelengths of 490 nm to 500 nm is defined as bluish green; the color of light in the range of wavelengths of 500 nm to 560 nm is defined as green; the color of light in the range of wavelengths of 560 nm to 580 nm is defined as yellowish green; the color of light in the range of wavelengths of 580 nm to 595 nm is defined as yellow; the color of light in the range of wavelengths of 595 nm to 610 nm is defined as orange; the color of light in the range of wavelengths of 610 nm to 750 nm is defined as red; and the color of light in the range of wavelengths of 750 nm to 800 nm is defined as purplish red. In this example, the color of light with a major wavelength in the range of wavelengths of 400 nm to 490 nm is defined as blue; the color of light with a major wavelength, which is greater than 490 nm and less than 595 nm, is defined as green; and the color of light with a major wavelength in the range of wavelengths of 595 nm to 800 nm is defined as red.

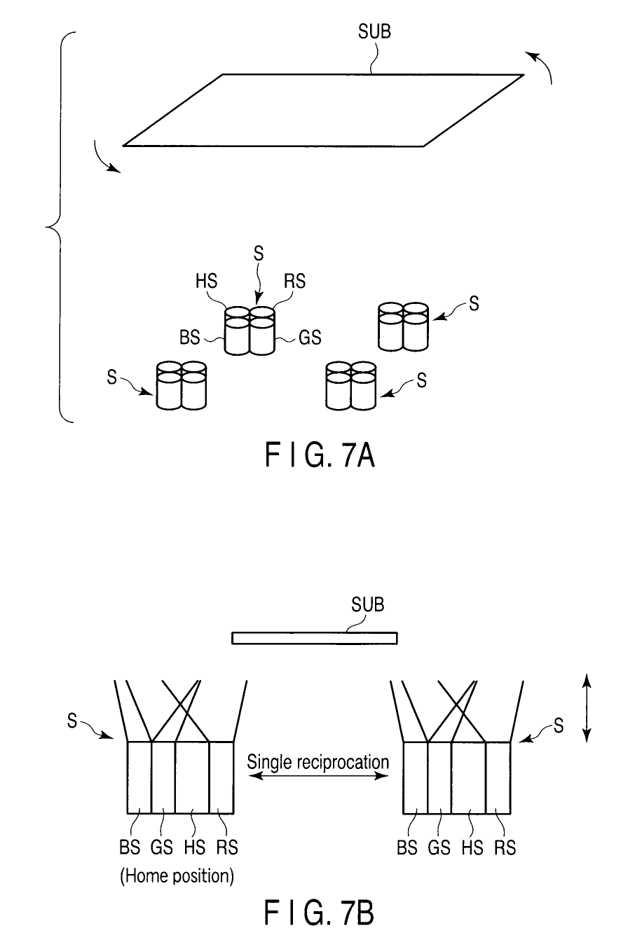

A description will now be given of an example of a manufacturing method of the organic EL display device having the above-described structure. FIG. 6 shows a process flow of the manufacturing method.

To start with, an array substrate, which has such a structure that the counter-electrode CE and organic layer ORG are removed from the above-described display panel DP, is prepared in an array step.

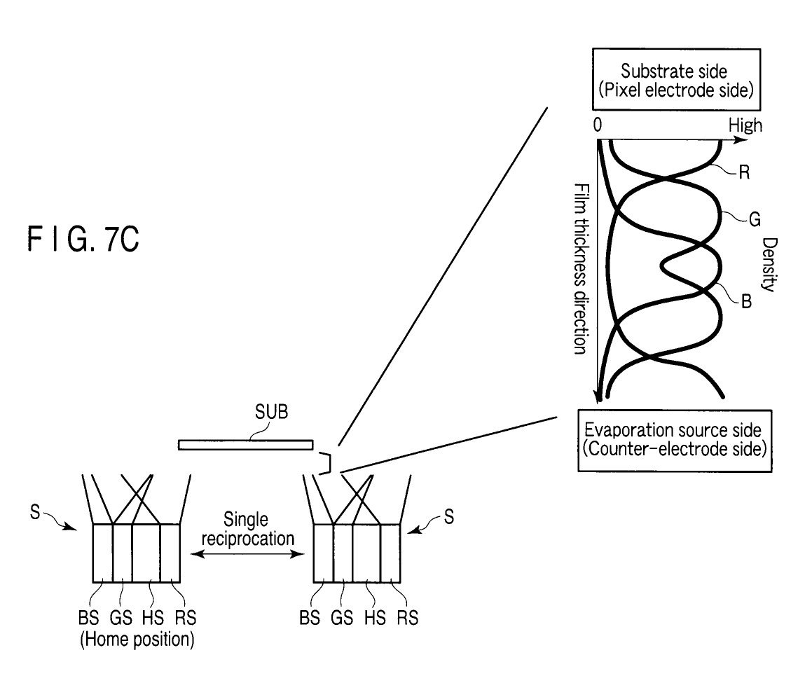

Then, an organic layer ORG is formed on the pixel electrode PE by a vacuum evaporation method. Examples of the evaporation method for forming the organic layer ORG include a method using an evaporation device to which point-source-type evaporation sources, as shown in FIG. 7A, are applied, and a method using an evaporation device to which a line-source-type evaporation source, as shown in FIG. 7B, is applied.

Specifically, in the evaporation device shown in FIG. 7A, point-source-type evaporation sources S are disposed in a chamber. The evaporation source S is configured to disperse a material source by heating a crucible by, e.g. a resistive heating method. Each evaporation source S includes a first evaporation source RS including a material source of the first light-emitting material EM1, a second evaporation source GS including a material source of the second light-emitting material EM2, a third evaporation source BS including a material source of the third light-emitting material EM3, and a fourth evaporation source HS including a material source of the host material HM. In the example shown in FIG. 7A, the evaporation sources S with this structure are fixed and disposed at four positions in the device.

On the other hand, the substrate SUB is held by a holding mechanism (not shown) such that its major surface, on which the pixel electrodes PE are formed, faces the four evaporation sources S. Not a fine mask in which openings are formed in association with individual pixels, but a rough mask, in which an opening corresponding to the display region is formed, is interposed between the substrate SUB and the evaporation sources S.

While the substrate SUB is being rotated by the holding mechanism, the evaporation sources S are heated and the respective material sources are dispersed. Thereby, the first light-emitting material EM1, second light-emitting material EM2, third light-emitting material EM3 and host material HM are co-evaporated. The organic layer ORG, which is thus formed, is a continuous film spreading over the display region.

Since the thus formed organic layer ORG is formed with no movement of the evaporation sources S, the density distribution of each of the first light-emitting material EM1, second light-emitting material EM2 and third light-emitting material EM3 is substantially uniform in the thickness direction of the organic layer ORG. In other words, in the case where the point-source-type evaporation sources are used, the organic layer ORG, which has the feature that each light-emitting material has a uniform density distribution in the film thickness direction from the pixel electrode PE toward the counter-electrode CE, is formed.

On the other hand, in the evaporation device shown in FIG. 7B, a line-source-type evaporation source S is disposed in a chamber. The evaporation source S has a shape which is elongated in the depth direction (i.e. a direction normal to the sheet face of FIG. 7B) of the substrate SUB. The evaporation source S has a length which is equal to or greater than the depth of the substrate SUB. The evaporation source S is configured to disperse a material source by heating a crucible by, e.g. a resistive heating method. The evaporation source S includes a first evaporation source RS including a material source of the first light-emitting material EM1, a second evaporation source GS including a material source of the second light-emitting material EM2, a third evaporation source BS including a material source of the third light-emitting material EM3, and a fourth evaporation source HS including a material source of the host material HM. The evaporation source S having this structure is configured to be movable in the width direction of the substrate SUB.

In the example shown in FIG. 7B, in the state in which the evaporation source S stands by in the home position (i.e. a position outside the position where the evaporation source S is just opposed to the substrate SUB), the first evaporation source RS, fourth evaporation source HS, second evaporation source GS and third evaporation source BS are closely arranged in the width direction in the evaporation source S in the named order from the one closest to the substrate SUB.

On the other hand, the substrate SUB is held by a holding mechanism (not shown) such that its major surface, on which the pixel electrodes PE are formed, faces the evaporation source S. Not a fine mask in which openings are formed in association with individual pixels, but a rough mask, in which an opening corresponding to the display region is formed, is interposed between the substrate SUB and the evaporation source S.

While the evaporation source S is being heated and the respective material sources are being dispersed, the evaporation source S is once reciprocated between the home position and the end of the substrate SUB. During this time, the first light-emitting material EM1, second light-emitting material EM2, third light-emitting material EM3 and host material HM are co-evaporated. The organic layer ORG, which is thus formed, is a continuous film spreading over the display region.

Since the thus formed organic layer ORG is formed with the movement of the evaporation source S, the first light-emitting material EM1, second light-emitting material EM2 and third light-emitting material EM3 have mutually different density distributions in the thickness direction of the organic layer ORG.

For example, in the case where the organic layer ORG is formed in the evaporation device having the evaporation source S with the structure shown in FIG. 7B, the densities of the respective light-emitting materials in the organic layer ORG have the following relationship in a first region near the pixel electrode PE:

the first light-emitting material EM1 (R)>the second light-emitting material EM2 (G)>the third light-emitting material EM3 (B).

The reason why this relationship is established is that the evaporation sources in the evaporation source S are arranged in the order of the first evaporation source RS, fourth evaporation source HS, second evaporation source GS and third evaporation source BS from the evaporation source closest to the substrate SUB.

In the organic layer ORG, the following relationship is established between the densities of the respective light-emitting materials in a second region which is located more on the counter-electrode CE side than the first region:

the second light-emitting material EM2 (G)>the first light-emitting material EM1 (R)=the third light-emitting material EM3 (B).

In addition, in the organic layer ORG, the following relationship is established between the densities of the respective light-emitting materials in a third region which is located in the vicinity of the counter-electrode CE:

the third light-emitting material EM3 (B)>the second light-emitting material EM2 (G)>the first light-emitting material EM1 (R).

In the case where the organic layer ORG is formed in the evaporation device including the evaporation source S having the structure shown in FIG. 7B, the densities of the respective light-emitting materials in the organic layer ORG have the relationship as shown in FIG. 7C. The density distribution of each light-emitting material is symmetric with respect to a substantially middle position in the film thickness direction because each light-emitting material is evaporated while the evaporation source S is being reciprocated.

In other words, in the case where the line-source-type evaporation source S is used, the organic layer ORG, which has the feature that the respective light-emitting materials have mutually different density distributions in the film thickness direction from the pixel electrode PE toward the counter-electrode CE, is formed.

Subsequently, electromagnetic waves are radiated on associated areas of the organic EL element OLED that is included in each of the pixel PX1, pixel PX2 and pixel PX3, so that any one of the first light-emitting material EM1, second light-emitting material EM2 and third light-emitting material EM3 may emit light. In the case where three kinds of light-emitting materials are included, the electromagnetic wave radiation step includes at least two exposure steps. In the pixel PX2 that emits green light, the light emission function of the first light-emitting material EM1 in the organic layer ORG is lost. In the pixel PX3 that emits blue light, the light emission functions of the first light-emitting material EM1 and second light-emitting material EM2 in the organic layer ORG are lost.

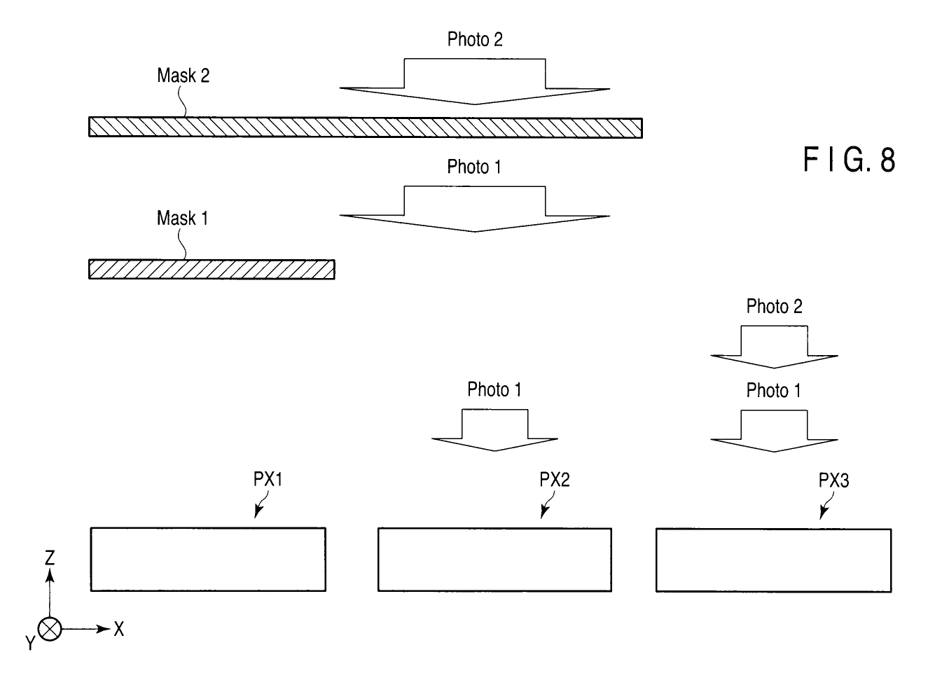

To be more specific, in an example shown in FIG. 8, to begin with, such an exposure condition is set in a first exposure step that the light emission function of the first light-emitting material EM1 is lost in regions that form the pixel PX2 and pixel PX3, and the associated areas are exposed. Specifically, the pixel PX1 is covered with a photomask (MASK1 in FIG. 8), and the pixel PX2 and pixel PX3 are exposed. The pixel PX2 and pixel PX3 are exposed with light having a peak wavelength of normalized absorbance of the first light-emitting material EM1, that is, light having a wavelength of 500 nm or more in the above-described example (PHOTO1). By this exposure, the light emission function of the first light-emitting material EM1 is lost. The details will be described later.

In a subsequent second exposure step, such an exposure condition is set that the light emission function of the second light-emitting material EM2 is lost in the region that forms the pixel PX3, and the associated area is exposed. Specifically, the pixel PX1 and pixel PX2 are covered with a photomask (MASK2 in FIG. 8), and the pixel PX3 is exposed. The pixel PX3 is exposed with light having a peak wavelength of normalized absorbance of the second light-emitting material EM2, that is, light having a wavelength of 400 nm or more in the above-described example (PHOTO2). By this exposure, the light emission function of the second light-emitting material EM2 is lost. The details will be described later.

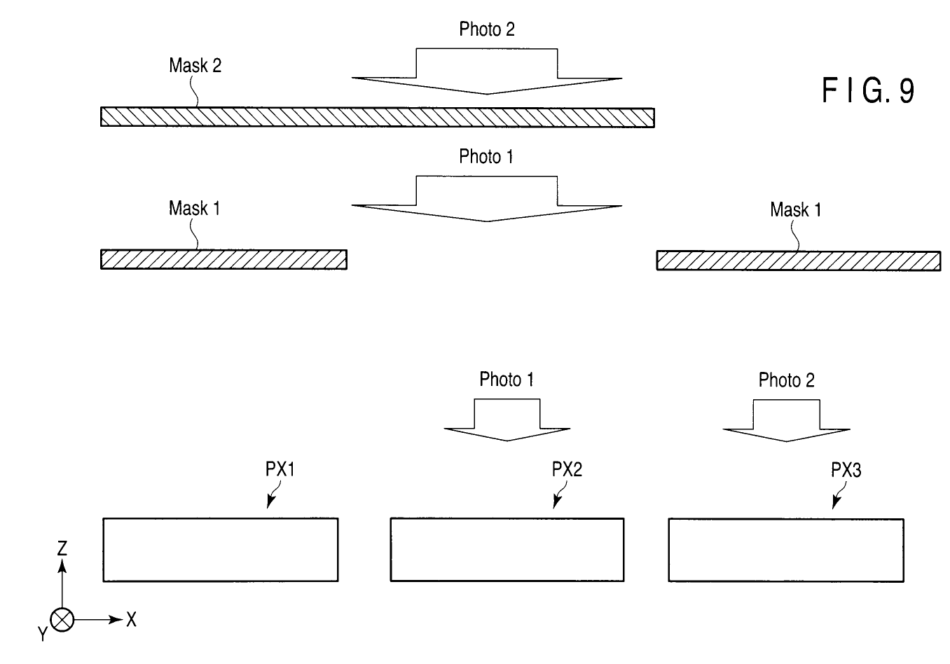

The electromagnetic radiation step is not limited to the example shown in FIG. 8. FIG. 9 shows another example. In this example, to begin with, such an exposure condition is set in a first exposure step that the light emission function of the first light-emitting material EM1 is lost in a region that forms the pixel PX2, and the associated area is exposed. Specifically, the pixel PX1 and pixel PX3 are covered with a photomask (MASK1 in FIG. 9), and the pixel PX2 is exposed. The pixel PX2 is exposed with light having a peak wavelength of normalized absorbance of the first light-emitting material EM1, that is, light having a wavelength of 500 nm or more in the above-described example (PHOTO1). By this exposure, the light emission function of the first light-emitting material EM1 is lost.

In a subsequent second exposure step, such an exposure condition is set that the light emission functions of the first light-emitting material EM1 and second light-emitting material EM2 are lost in the region that forms the pixel PX3, and the associated area is exposed. Specifically, the pixel PX1 and pixel PX2 are covered with a photomask (MASK2 in FIG. 9), and the pixel PX3 is exposed. The pixel PX3 is exposed with light having a peak wavelength range of normalized absorbance of the first light-emitting material EM1 and second light-emitting material EM2, that is, light having a wavelength range of at least 400 nm to 500 nm in the above-described example (PHOTO2). By this exposure, the light emission functions of the first light-emitting material EM1 and second light-emitting material EM2 are lost at the same time.

Thereafter, a counter-electrode CE is formed on the organic layer ORG by, e.g. a vacuum evaporation method. In the present example, an aluminum layer with a thickness of 150 nm was formed as the counter-electrode CE. The counter-electrode CE was formed as a continuous film extending over the display region. In this example, the counter-electrode CE also functions as a reflective layer for extracting emission light from the organic layer ORG toward the substrate SUB side.

Further, the organic EL element OLED is sealed, and the video signal line driver XDR and scanning signal line driver YDR are mounted on the display panel DP. In the above-described manner, the organic EL display device shown in FIG. 1 and FIG. 2 is obtained.

In this example, the patterning precision that is required for the opening corresponding to the display region may be lower by an order of magnitude or more than the patterning precision in the case of selectively applying light-emitting materials on the respective pixels. Accordingly, the precision of opening that is required for the rough mask is low, and the opening can sufficiently be formed even by mask evaporation using a metallic mask.

On the other hand, as regards the patterning precision in the exposure step of radiating electromagnetic waves on the individual pixels, since photomasks are used, a target pixel for irradiation and a pixel other than the target pixel can be discriminated with high precision. Specifically, even in the case where the pixel size is small, the electromagnetic wave radiation process can be carried out without radiating electromagnetic waves on the region other than the region of the pixel that is the object of radiation.

In the meantime, in the case where one organic EL element OLED includes a plurality of light-emitting materials EM1 to EM3, it is possible that not only light of one color but also light of other colors may be emitted. Normally, with the structure in which the light-emitting materials EM1 to EM3 are simply mixed, the pixels PX1 to PX3 emit light of the same color, and full-color display cannot be obtained.

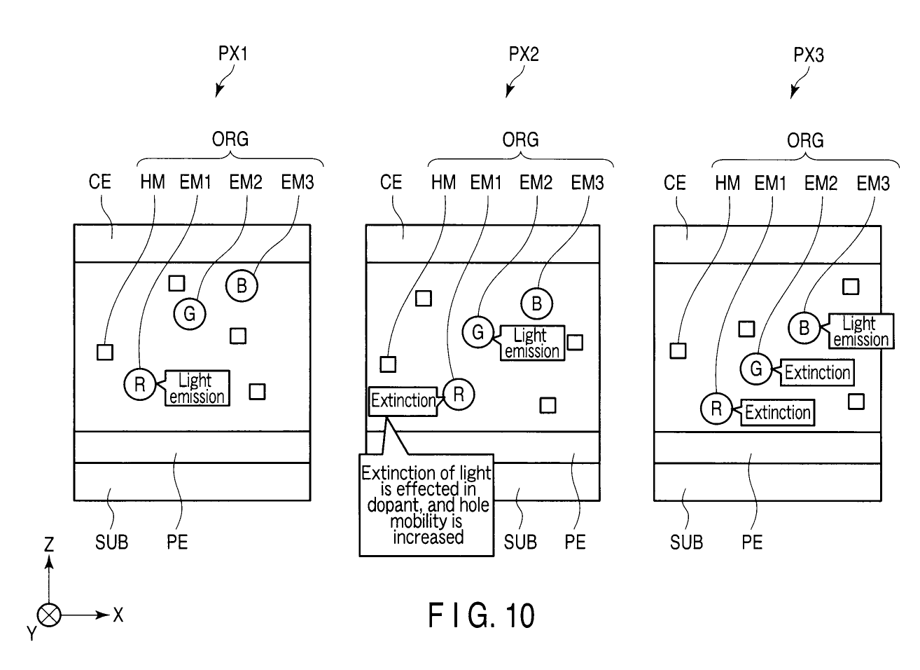

To cope with this, in the present invention, a pixel, which is to be irradiated with electromagnetic waves, and other pixels are separated in the exposure step by using a photomask, and the color of emission light of each pixel is controlled. FIG. 10 shows one principle for controlling the colors of emission light of the pixels in the invention.

In the organic layer ORG having the structure in which the host material HM and light-emitting materials EM1 to EM3 are mixed, the first light-emitting material EM1 of red basically tends to easily emit light. The reason for this is as follows. In the system in which the host material HM, third light-emitting material EM3, second light-emitting material EM2 and first light-emitting material EM1 co-exist, if the excitation energy is higher in this order, energy transfer occurs from the host material HM, which is excited by re-combination of holes and electrons, to the third light-emitting material EM3 by Förster transition. Further, energy transfer occurs to the first light-emitting material EM1 via the second light-emitting material EM2. In short, in this system, the first light-emitting material EM1, which has the lowest excitation energy, most easily emits light from the excited state. Therefore, in the pixel PX1 on which no electromagnetic wave is radiated, red light is emitted.

On the other hand, in the pixel PX2 in which the first light-emitting material EM1 has been irradiated with electromagnetic waves, the red dopant material that is the first light-emitting material EM1 absorbs the electromagnetic waves, and the material is decomposed or polymerized, or the molecular structure of the material is changed. As a result, the red dopant material no longer emits red light in a so-called extinction state (corresponding to a state in which the light emission function is lost). This state substantially corresponds to the system in which the host material HM, the third light-emitting material EM3 and the second light-emitting material EM2 co-exist. Accordingly, energy transfer occurs from the excited host material HM to the third light-emitting material EM3, and further energy transfer occurs to the second light-emitting material EM2. In short, in this system, the second light-emitting material EM2, which has the lowest excitation energy (the next lowest excitation energy to the first light-emitting material), most easily emits light from the excited state. Therefore, in the pixel PX2, green light is emitted.

Further, in the pixel PX3 in which the first light-emitting material EM1 and second light-emitting material EM2 have been irradiated with electromagnetic waves, the red dopant material that is the first light-emitting material EM1 and the green dopant material that is the second light-emitting material EM2 absorb the electromagnetic waves, and these materials are decomposed or polymerized, or the molecular structures of the materials are changed. As a result, the red dopant material and green dopant material no longer emit red light and green light in a so-called extinction state (corresponding to a state in which the light emission function is lost). This state substantially corresponds to the system in which the host material HM and the third light-emitting material EM3 co-exist. Accordingly, energy transfer occurs only from the excited host material HM to the third light-emitting material EM3. In short, in this system, the third light-emitting material EM3, which has the lowest excitation energy (the next lowest excitation energy to the second light-emitting material), most easily emits light from the excited state. Therefore, in the pixel PX3, blue light is emitted.

As has been described above, in the present invention, the organic layer of each pixel is configured to include a mixture layer including a plurality of kinds of light-emitting materials which emit lights of different colors, and in each pixel a single light-emitting material selectively emits light. Thereby, without using a metallic fine mask for selectively forming organic layers in association with RGB pixels, it becomes possible to emit lights of colors corresponding to the RGB pixels and to obtain full-color display.

In the case of the evaporation using the fine mask, a useless film may possibly form on the mask, and the opening of the pixel may be filled. Consequently, the film formation rate of the organic film, which is formed in the pixel, lowers, and a greater amount of material is consumed. As a result, the number of times of cleaning of the mask increases. By contrast, in the present invention, the opening size is large, and only the rough mask, on which a useless film does not easily form, is used. Therefore, compared to the case of using the fine mask, the productivity is high and the environmental load is low.

Further, with single-time co-evaporation, the mixture layer including the plural kinds of light-emitting materials can be formed in each pixel. Thus, the manufacturing time can be decreased, and the manufacturing cost can be reduced.

Therefore, the present invention can provide a high-definition, large-sized full-color organic EL display device, with eco-friendliness and high productivity.

In the above-described manner, the organic EL display device of the present invention, as shown in FIG. 1 and FIG. 2, was obtained.

As a result, red light was emitted in the pixel PX1, green light was emitted in the pixel PX2 and blue light was emitted in the pixel PX3, without mixture of colors. The light emission efficiency was 8 cd/A in red, 10 cd/A in green, and 3 cd/A in blue. As regards the hues of the respective pixels, the chromaticity coordinates on a chromaticity diagram of the red light emitted in the pixel PX1 were (0.65, 0.35), the chromaticity coordinates of the green light emitted in the pixel PX2 were (0.30, 0.60), and the chromaticity coordinates of the blue light emitted in the pixel PX3 were (0.14, 0.12).

The above values are values which were obtained by measuring the luminance and chromaticity (x, y) of each emission light, with the pixels PX1 to PX3 being successively turned on, under the condition that reference white (C) was displayed with the luminance of 100 cd/m² (x, y)=(0.31, 0.315) when the screen was viewed in the frontal direction.

In the present example, the pixel PX1, pixel PX2 and pixel PX3 have the same size. For example, in order to uniformize the luminance degradation life of the emission color of each pixel, the sizes of the pixels may be varied. Thereby, easy coloring of white can be prevented.

Other examples of the present invention will be described below.

### EXAMPLE 2

### A Case in Which Layers HIL, HTL, ETL and EIL are Provided in Addition to the Mixture Layer EML

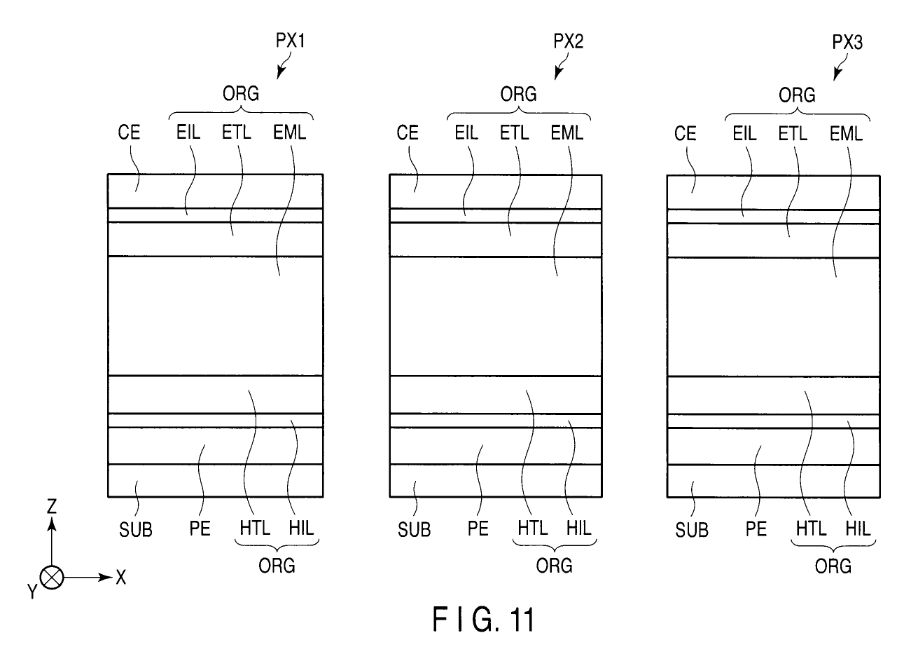

FIG. 11 shows the structure according to Example 2. FIG. 11 is a cross-sectional view which schematically shows another example of the structure that is adoptable in the organic EL element included in the display device shown in FIG. 2. In Example 2, the organic layer ORG of each pixel includes, in addition to the mixture layer EML including the host material HM, first light-emitting material EM1, second light-emitting material EM2 and third light-emitting material EM3, a hole injection layer HIL and a hole transport layer HTL on the pixel electrode PE side of the mixture layer EML, and an electron transport layer ETL and an electron injection layer EIL on the counter-electrode CE side of the mixture layer EML.

As the hole injection layer HIL, an amorphous carbon layer with a thickness of 10 nm was formed. As the hole transport layer HTL, a layer of N,N′-diphenyl-N,N′-bis(1-naphtylphenyl)-1,1′-biphenyl-4,4′-diamine(α-NPD), which has a thickness of 30 nm, was formed by vacuum evaporation. The hole injection layer HIL and hole transport layer HTL were formed as continuous films spreading over the display region.

As the electron transport layer ETL, an Alq₃ layer with a thickness of 30 nm was used. As the electron injection layer EIL, a lithium fluoride layer with a thickness of 1 nm was used. The electron transport layer ETL and electron injection layer EIL were formed by vacuum evaporation, and were formed as continuous films spreading over the display region.

Thereby, the balance between holes and electrons in the light-emitting layer is improved, and the light emission efficiency is enhanced. In addition, hole injection, hole transport, electron injection and electron transport are improved, and the driving voltage is reduced.

### EXAMPLE 3

### A Case of Top Emission

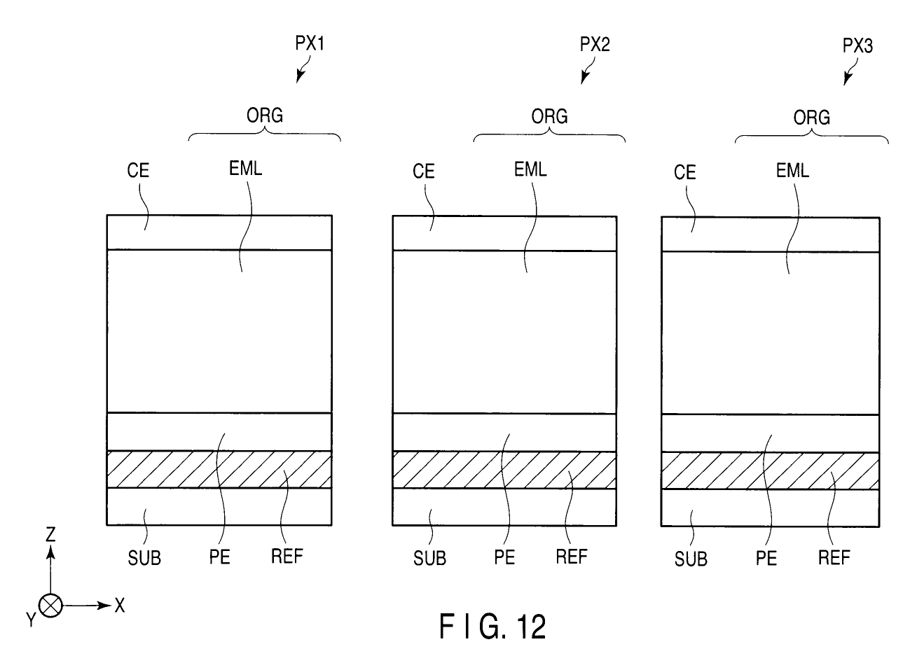

FIG. 12 shows the structure according to Example 3. FIG. 12 is a cross-sectional view which schematically shows still another example of the structure that is adoptable in the organic EL element included in the display device shown in FIG. 2. In Example 3, a reflective layer REF was formed on the pixel electrode PE. Thereby, emission light is extracted to the counter-electrode CE side. The counter-electrode CE was formed as a semi-transparent electrode by evaporation using a mixture of magnesium and silver. The thickness of the counter-electrode CE was set at 20 nm, and the counter-electrode CE was formed as a continuous film spreading over the display region. As regards the ratio between magnesium and silver, the silver content was set at 60 to 98% in order to obtain high light transmissivity.

Thereby, unlike the structure in which emission light is extracted to the substrate SUB side, light can be extracted without restriction of the aperture ratio due to the thin-film transistors and their wiring. Therefore, even with a high-definition panel having a small pixel size, a sufficient light emission area of the OLED element can be secured, and the power-on degradation (lifetime) of the OLED element is improved.

### EXAMPLE 4

### A Case in Which Layers HIL, HTL, ETL and EIL and an Optical Matching Layer MC are Added in the Top Emission Structure

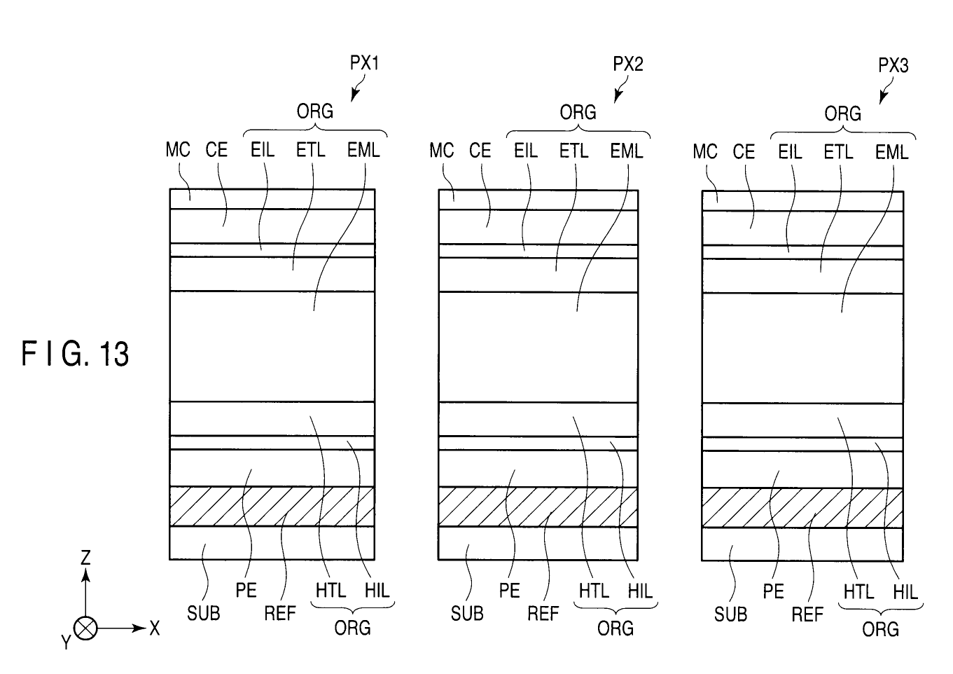

FIG. 13 shows the structure according to Example 4. FIG. 13 is a cross-sectional view which schematically shows still another example of the structure that is adoptable in the organic EL element included in the display device shown in FIG. 2. In the structure shown in FIG. 13, a hole injection layer HIL, a hole transport layer HTL, an electron transport layer ETL and an electron injection layer EIL were added to the structure of FIG. 12, and further an optical matching layer MC was formed on the counter-electrode CE.

The optical matching layer MC is a light-transmissive layer, and effects optical matching with a gas layer of nitrogen, or the like, which is present in a gap between the substrate SUB and the sealing substrate SUB2. The refractive index of the optical matching layer MC is substantially equal to the refractive index of the organic layer ORG. For instance, as the optical matching layer MC, use may be made of a transparent inorganic insulating layer such as an SiON layer, a transparent inorganic conductive layer such as an ITO layer, or a transparent organic layer such as a layer included in the organic layer ORG. If the optical matching layer MC is used, the light extraction efficiency can be enhanced. In the present example, the thickness of the pixel electrode PE was set at 100 nm, and the thickness of the hole transport layer HTL was set at 75 nm. The optical matching layer MC was set at 70 nm.

Thereby, compared to Example 3, the light emission efficiency was successfully increased four times. In the case where the white luminance was set at the same level as in Example 3, the power consumption was successfully reduced to ¼.

### EXAMPLE 5

### A Case in Which Layers HIL, HTL, ETL and EIL, an Optical Matching Layer MC and an RGB Interference Condition Adjusting Layer MC2 are Added in the Top Emission Structure

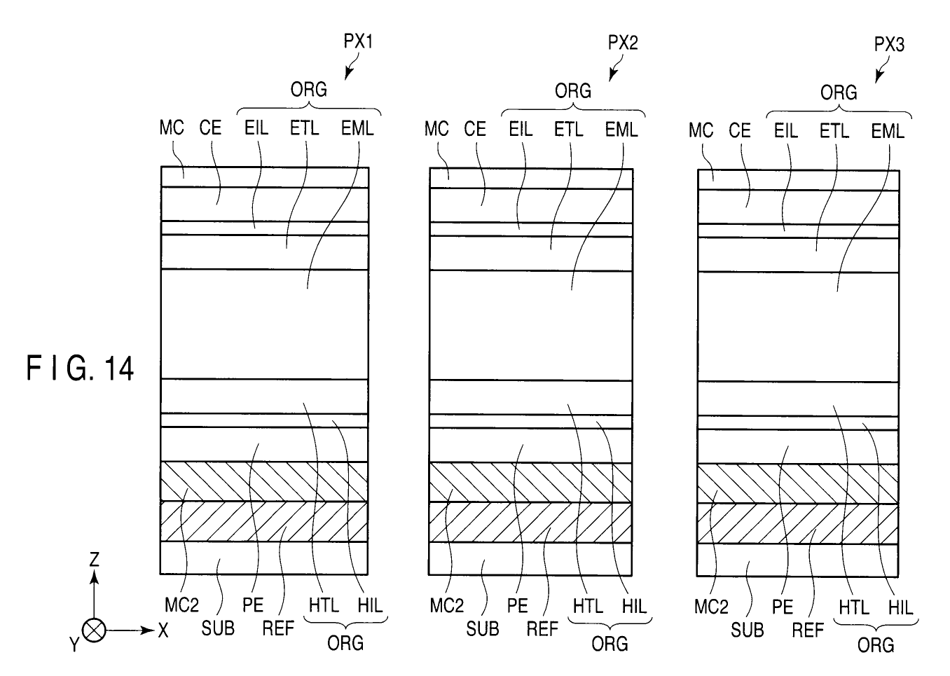

FIG. 14 shows the structure according to Example 5. FIG. 14 is a cross-sectional view which schematically shows still another example of the structure that is adoptable in the organic EL element included in the display device shown in FIG. 2. In the structure shown in FIG. 14, a layer MC2, which adjusts the interference condition of the RGB pixels PX1, PX2 and PX3, was formed on the reflective layer REF in the structure of FIG. 13.

The interference condition adjusting layer MC2 is a light-transmissive layer. In the case of the top emission structure as in this Example 5, it is necessary to optimally design the optical path length between the reflective layer REF and the counter-electrode CE in accordance with the wavelength of the emission light color. In particular, in the same order of interference, the optimal optical path length (resonance condition) differs between the red R, green G and blue B due to a difference between their emission light wavelengths. Since the interference condition adjusting layer MC2, which provides an optical path length corresponding to a least common multiple of ¼ of the three color emission light wavelengths, is formed between the reflective layer REF and the counter-electrode CE, it becomes possible to efficiently extract emission lights of red, green and blue of the pixels PX1 to PX3, to improve the light emission efficiency and to reduce the power consumption.

The refractive index of the interference condition adjusting layer MC2 is substantially equal to the refractive index of the organic layer ORG. For instance, as the interference condition adjusting layer MC2, use may be made of a transparent inorganic insulating layer such as an SiN layer, a transparent inorganic conductive layer such as an ITO layer, or a transparent organic layer such as a layer included in the organic layer ORG. In the present example, the thickness of the hole transport layer HTL was set at 40 nm, SiN was used for the interference condition adjusting layer MC2, and the thickness of the interference condition adjusting layer MC2 was set at 410 nm.

Thereby, compared to Example 3, the light emission efficiency was successfully increased six times, and the power consumption was successfully reduced. In this example, the color purity of each of red, green and blue was improved, and the color reproduction range was successfully set at 100% or more (relative to the NTSC ratio).

### EXAMPLE 6

### An Example in Which the Interference Condition Adjusting Layer MC2 is Removed from Only the Blue Pixel PX3 in the Top Emission Structure

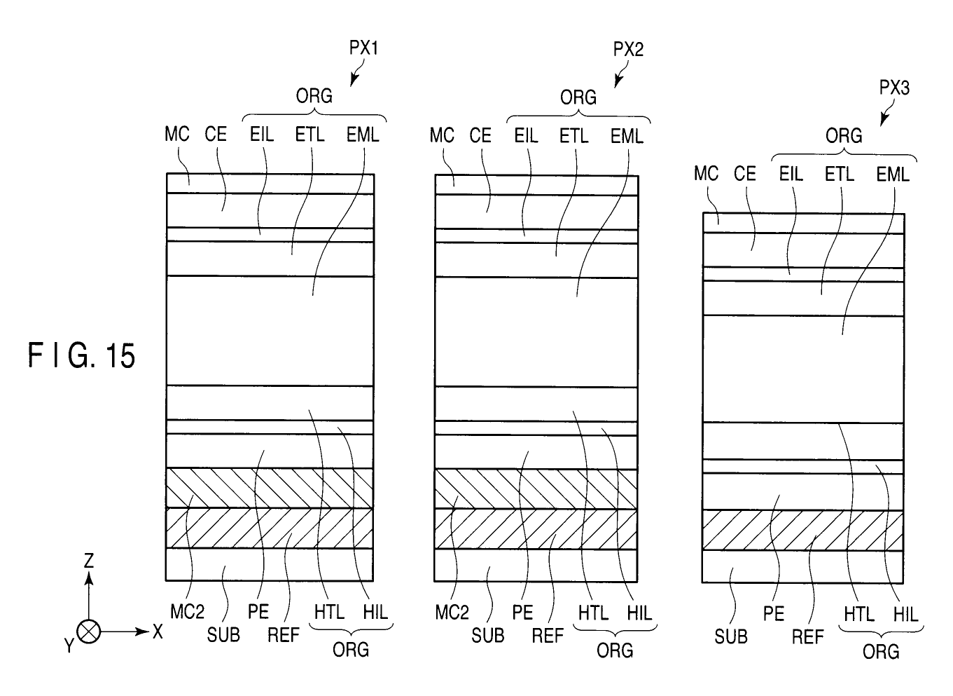

FIG. 15 shows the structure according to Example 6. FIG. 15 is a cross-sectional view which schematically shows still another example of the structure that is adoptable in the organic EL element included in the display device shown in FIG. 2. In the structure shown in FIG. 15, the interference condition adjusting layer MC2 of the pixel PX3 (blue) was removed from the structure of FIG. 14.

Thereby, the interference condition (resonance condition) can more easily be matched between the respective color pixels, and it becomes possible to enhance the efficiency and to improve the purity of each color. In this example, the thickness of the interference condition adjusting layer MC2 was set at 390 nm in accordance with only red and green.

Hence, the light emission efficiency was improved and successfully increased 1.5 times, compared to Example 4, and the power consumption was successfully reduced.

### EXAMPLE 7

### An Example in Which an Irregular Scattering Layer is Formed in the Top Emission Structure

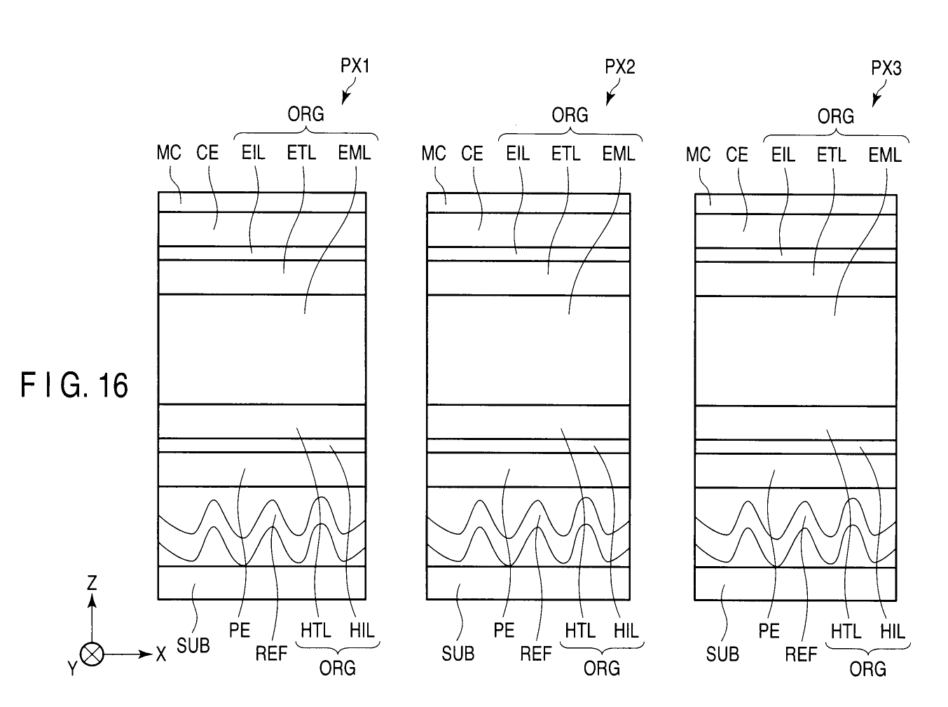

FIG. 16 shows the structure according to Example 7. FIG. 16 is a cross-sectional view which schematically shows still another example of the structure that is adoptable in the organic EL element included in the display device shown in FIG. 2. In the structure shown in FIG. 16, an irregular scattering layer structure, which eliminates a resonance state of top-emission light, was formed by using a reflective layer REF and an organic material in the structure shown in FIG. 13.

Thereby, the interference condition (resonance condition) is eliminated, and the film thickness adjustment of each organic EL element becomes needless.

### EXAMPLE 8

### An Example in Which an Irregular Scattering Layer is Formed in the Pixel PX1 (Red) and Pixel PX2 (Green) in the Top Emission Structure

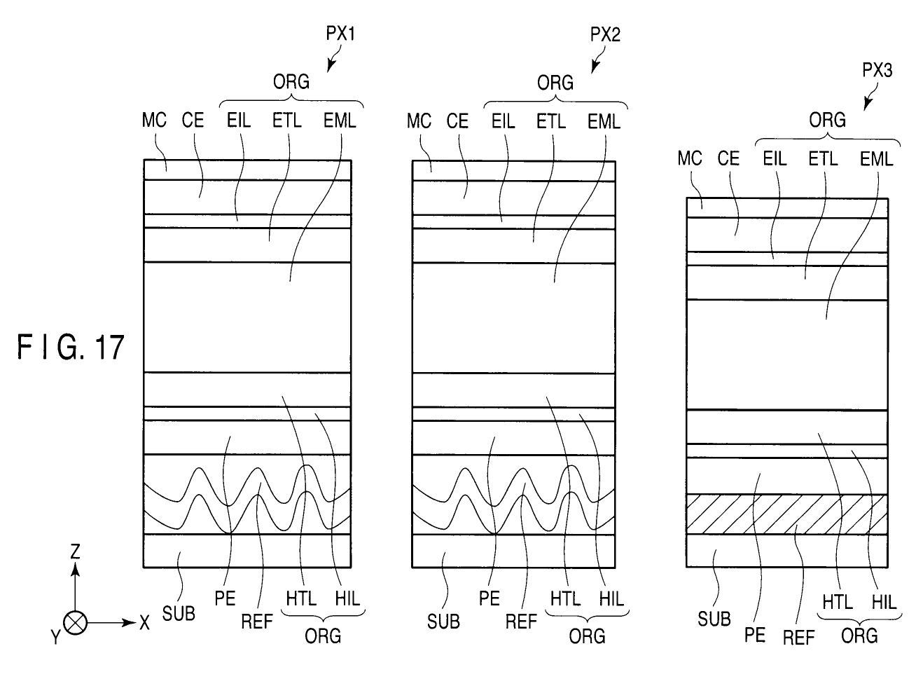

FIG. 17 shows the structure according to Example 8. FIG. 17 is a cross-sectional view which schematically shows still another example of the structure that is adoptable in the organic EL element included in the display device shown in FIG. 2. In the structure shown in FIG. 17, an irregular scattering layer structure, which eliminates a resonance state of top-emission light, was formed by using a reflective layer REF and an organic material in the pixel PX1 (red) and pixel PX2 (green) in the structure shown in FIG. 13.

Thereby, it should suffice if the interference condition (resonance condition) is designed in accordance with only the pixel PX3 (blue). The efficiency of blue light emission, which is particularly low in efficiency and is high in power consumption, can be improved, and the purity of blue can be enhanced.

### EXAMPLE 9

### A Case in Which a Partition Insulation Layer PI (Rib) is Not Used

In the structure of Example 9, the partition insulation layer PI, which is formed between pixels and is normally used in display devices using OLED elements, is not formed. The reason for this is that in the present invention a metallic mask not used, so there is no need to provide a partition insulation layer for supporting the metallic mask at the time of vacuum evaporation.

Thereby, the step of forming the partition insulation layer PI can be omitted, the material that is used can be reduced, and the environmental load can further be reduced.

In the above-described examples, the organic EL display device includes three kinds of organic EL elements which emit lights of different colors. Alternatively, the organic EL display device may include, as organic EL elements, only two kinds of organic EL elements which emit lights of different colors, or four or more kinds of organic EL elements which emit lights of different colors.

The present invention is not limited directly to the above-described embodiments. In practice, the structural elements can be modified and embodied without departing from the spirit of the invention. Various inventions can be made by properly combining the structural elements disclosed in the embodiments. For example, some structural elements may be omitted from all the structural elements disclosed in the embodiments. Furthermore, structural elements in different embodiments may properly be combined.

What is claimed is:

1. An organic EL display device comprising:
a first organic EL element which emits light of a first color and a second organic EL element which emits light of a second color that differs from the first color, the first organic EL element and the second organic EL element being arranged on a substrate,
wherein each of the first organic EL element and the second organic EL element includes a first electrode, a second electrode which is opposed to the first electrode, and an organic layer which is interposed between the first electrode and the second electrode,
the organic layer of the first organic EL element and the organic layer of the second organic EL element are formed of an identical material, and
a light emission function of the first color is substantially lost in the organic layer of the second organic EL element.

2. The organic EL display device according to claim 1, wherein the organic layer is a continuous film spreading over a display region.

3. The organic EL display device according to claim 1, wherein an emission light color of the first organic EL element has a longer wavelength than an emission light color of the second organic EL element.

4. The organic EL display device according to claim 1, wherein the organic layer of each of the first organic EL element and the second organic EL element includes a mixture layer in which a host material, a first light-emitting material which emits light of the first color, and a second light-emitting material, which emits light of the second color that has a less wavelength than the first color, are mixed.

5. The organic EL display device according to claim 4, wherein a light emission function of the first light-emitting material is lost in the mixture layer of the second organic EL element.

6. The organic EL display device according to claim 4, wherein the host material, the first light-emitting material and the second light-emitting material are deposited by a co-evaporation method.

7. The organic EL display device according to claim 1, wherein the first electrode is an anode and the second electrode is a cathode, and
the organic layer includes a hole injection layer and a hole transport layer on the first electrode side thereof, and includes an electron transport layer and an electron injection layer on the second electrode side thereof.

8. The organic EL display device according to claim 1, further comprising a reflective layer on a side of the first electrode, which is opposite to the organic layer.

9. The organic EL display device according to claim 1, further comprising an optical matching layer on a side of the second electrode, which is opposite to the organic layer.

10. The organic EL display device according to claim 8, further comprising an interference condition adjusting layer between the first electrode and the reflective layer.

11. The organic EL display device according to claim 1, further comprising an irregular scattering layer, which includes a reflective layer, on an outside of the first electrode, relative to the organic layer.

12. The organic EL display device according to claim 4, wherein a density distribution of the two kinds of light-emitting materials included in the mixture layer is uniform in a film thickness direction in the organic layer.

13. The organic EL display device according to claim 12, wherein the light-emitting materials are deposited by a co-evaporation method using a point-source-type evaporation source.

14. The organic EL display device according to claim 4, wherein density distributions of the two kinds of light-emitting materials included in the mixture layer are different in a film thickness direction in the organic layer.

15. The organic EL display device according to claim 14, wherein the light-emitting materials are deposited by a co-evaporation method using a line-source-type evaporation source.

16. A method of manufacturing an organic EL display device including a first organic EL element which emits light of a first color and a second organic EL element which emits light of a second color that differs from the first color, the first organic EL element and the second organic EL element being arranged on a substrate, wherein each of the first organic EL element and the second organic EL element includes a first electrode, a second electrode which is opposed to the first electrode, and an organic layer which is interposed between the first electrode and the second electrode, a step of forming the organic layer comprising:
a step of forming a mixture layer, in which a host material, a first light-emitting material with a light emission function of the first color and a second light-emitting material with a light emission function of the second color are mixed, in a region where the first organic EL element and the second organic EL element are formed; and
a step of covering a region, where the first organic EL element is formed, with a mask, and irradiating a region, where the second organic EL element is formed, with electromagnetic waves which are capable of losing the light emission function of the first light-emitting material.

17. The method of manufacturing an organic EL display device, according to claim 16, wherein in the step of forming the mixture layer, use is made of a point-source-type evaporation source which includes material sources of the host material, the first light-emitting material and the second light-emitting material.

18. The method of manufacturing an organic EL display device, according to claim 16, wherein in the step of forming the mixture layer, use is made of a line-source-type evaporation source which includes material sources of the host material, the first light-emitting material and the second light-emitting material.
